(19) United States
(12) Patent Application Publication
(10) Pub. No.: US 2022/0328290 A1
(43) Pub. Date: Oct. 13, 2022

(54) MOVEABLE EDGE RINGS FOR SUBSTRATE PROCESSING SYSTEMS

(71) Applicant: LAM RESEARCH COPORATION, Fremont, CA (US)

(72) Inventors: Rohini MISHRA, Dublin, CA (US); Saravanapriyan SRIRAMAN, Fremont, CA (US)

(21) Appl. No.: 17/633,727

(22) PCT Filed: Aug. 7, 2020
(86) PCT No.: PCT/US2020/045389

§ 371 Date: Feb. 8, 2022

Related U.S. Application Data
(60) Provisional application No. 62/886,692, filed on Aug. 14, 2019.

(51) Int. Cl. H01J 37/32

(52) U.S. Cl. CPC H01J 37/32715; H01J 37/32385; H01J 37/32642

(57) ABSTRACT

A substrate support includes an outer edge ring configured to be raised and lowered relative to the substrate support via one or more lift pins. The outer edge ring is further configured to interface with a guide feature extending upward from a middle ring of the substrate support. An inner edge ring is located radially inward of the outer edge ring and is configured to be raised and lowered, independently of the outer edge ring, relative to the substrate support via one or more lift pins.

### CROSS-REFERENCE TO RELATED APPLICATIONS

This application claims the benefit of U.S. Provisional Application No. 62/886,692, filed on Aug. 14, 2019. The entire disclosure of the application referenced above is incorporated herein by reference.

### FIELD

The present disclosure relates to moveable edge rings in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), conductor etch, and/or other etch, deposition, or cleaning processes. A substrate may be arranged on a substrate support, such as a pedestal, an electrostatic chuck (ESC), etc. in a processing chamber of the substrate processing system. During etching, gas mixtures including one or more precursors may be introduced into the processing chamber and plasma may be used to initiate chemical reactions.

The substrate support may include a ceramic layer arranged to support a wafer. For example, the wafer may be clamped to the ceramic layer during processing. The substrate support may include an edge ring arranged around an outer portion (e.g., outside of and/or adjacent to a perimeter) of the substrate support. The edge ring may be provided to confine plasma to a volume above the substrate, protect the substrate support from erosion caused by the plasma, etc.

### SUMMARY

A substrate support includes an outer edge ring configured to be raised and lowered relative to the substrate support via one or more lift pins. The outer edge ring is further configured to interface with a guide feature extending upward from a middle ring of the substrate support. An inner edge ring is located radially inward of the outer edge ring and is configured to be raised and lowered, independently of the outer edge ring, relative to the substrate support via one or more lift pins.

In other features, the substrate support includes a fixed inner ring located radially inward of the inner edge ring. The substrate support includes the middle ring including the guide feature. The guide feature corresponds to a raised annular rim. The outer edge ring includes an annular groove arranged to receive the raised annular rim. A system includes the substrate support and further includes a controller configured to adjust a position of the outer edge ring to adjust an inflection point of a plasma sheath that determines a tunable radial range of the plasma sheath and to adjust a position of the inner edge ring to adjust the plasma sheath within the tunable radial range.

A substrate support includes an inner edge ring, an outer edge ring located radially outward of the inner edge ring, and a bottom ring. The outer edge ring is arranged on the bottom ring, the bottom ring is configured to be raised and lowered relative to the substrate support via one or more lift pins, and raising and lowering the bottom ring correspondingly raised and lowers the outer edge ring relative to the substrate support.

In other features, the substrate support further includes a fixed inner edge ring located radially inward of the outer edge ring. The substrate support further includes an isolation ring, the bottom ring is arranged on the isolation ring, and the isolation ring includes visa arranged to receive the one or more lift pins. The one or more lift pins pass through the vias radially outward of a baseplate of the substrate support. A system includes the substrate support and further includes a controller configured to adjust a position of the outer edge ring to adjust a plasma sheath.

A substrate support includes an outer edge ring configured to be raised and lowered relative to the substrate support via one or more lift pins and further configured to interface with a guide feature extending upward from a middle ring of the substrate support the edge ring, an inner edge ring located radially inward of the outer edge ring, and a bottom ring including a stepped outer portion. The outer edge ring is arranged on the stepped outer portion of the bottom ring and the stepped outer portion includes via arranged to receive the one or more lift pins.

In other features, the substrate support further includes the middle ring including the guide feature. The guide feature corresponds to a raised annular rim. The outer edge ring includes an annular groove arranged to receive the raised annular rim. A system includes the substrate support and further includes a controller configured to adjust a position of the outer edge ring to adjust a plasma sheath.

In other features, at least one lift pin of the one or more lift pins is conductive. The at least one lift pin is configured to receive power provided to the substrate support. The outer edge ring is configured to receive the power from the at least one lift pin. The outer edge ring includes an embedded metal mesh arranged to contact the at least one lift pin.

A substrate support includes a middle ring including an inner portion and a guide feature extending upward from the middle ring and an outer edge ring located radially outward of the inner portion of the middle ring and configured to be raised and lowered relative to the substrate support via one or more lift pins. The outer edge ring is further configured to interface with the guide feature. At least one of respective upper surfaces of the inner portion of the middle ring and the outer edge ring is chamfered.

In other features, the substrate support further includes a side ring including a stepped inner portion, the outer edge ring is arranged on the stepped inner portion of the side ring, and the stepped inner portion includes via arranged to receive the one or more lift pins. The guide feature corresponds to a raised annular rim. The outer edge ring includes an annular groove arranged to receive the raised annular rim. A system includes the substrate support and further includes a controller configured to adjust a position of the outer edge ring to adjust a plasma sheath.

In other features, each of the respective upper surfaces of the inner portion of the middle ring and the outer edge ring is chamfered. The at least of the respective upper surfaces of the inner portion of the middle ring and the outer edge ring slopes upward as a radial distance increases.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system according to the present disclosure;

FIG. 2A shows an example moveable edge ring in a lowered position according to the present disclosure;

FIG. 2B shows an example moveable edge ring in a raised position according to the present disclosure;

FIGS. 3A, 3B, 3C, 3D, 3E, and 3F show first example substrate supports including moveable edge rings according to the present disclosure;

FIG. 3G is a graph illustrating tunability of an etch rate of a substrate relative to a radius of the substrate according to the present disclosure;

FIGS. 4A, 4B, 4C, and 4D show second example substrate supports including a moveable edge ring according to the present disclosure;

FIGS. 5A, 5B, 5C, and 5D show third example substrate supports including a moveable edge ring according to the present disclosure; and

FIGS. 6A, 6B, and 6C show fourth example substrate supports including a moveable edge ring according to the present disclosure.

In the drawings, reference numbers may be reused to identify similar and/or identical elements.

### DETAILED DESCRIPTION

A substrate support in a substrate processing system may include an edge ring. An upper surface of the edge ring may extend above an upper surface of the substrate support, causing the upper surface of the substrate support (and, in some examples, an upper surface of a substrate arranged on the substrate support) to be recessed relative to the edge ring. This recess may be referred to as a pocket. A distance between the upper surface of the edge ring and the upper surface of the substrate may be referred to as a “pocket depth.” Generally, the pocket depth is fixed according to a height of the edge ring relative to the upper surface of the substrate.

Some aspects of etch processing may vary due to characteristics of the substrate processing system, the substrate, gas mixtures, etc. For example, flow patterns, and therefore an etch rate and etch uniformity, may vary according to the pocket depth of the edge ring, edge ring geometry (i.e., shape), as well as other variables including, but not limited to, gas flow rates, gas species, injection angle, injection position, etc. Accordingly, varying the configuration of the edge ring (e.g., including edge ring height and/or geometry) may modify the gas velocity profile across the surface of the substrate.

Some substrate processing systems may implement moveable (e.g., tunable) edge rings and/or replaceable edge rings. In one example, a height of a moveable edge may be adjusted during processing to control etch uniformity. The edge ring may be coupled to an actuator configured to raise and lower the edge ring in response to a controller, user interface, etc. In one example, a controller of the substrate processing system controls the height of the edge ring during a process, between process steps, etc. according to a particular recipe being performed and associated gas injection parameters. Further, edge rings and other components may comprise consumable materials that wear/erode over time. Accordingly, the height of the edge ring may be adjusted to compensate for erosion.

In other examples, edge rings may be removable and replaceable (e.g., to replace eroded or damaged edge rings, to replace an edge ring with an edge ring having different geometry, etc.). Examples of substrate processing systems implementing moveable and replaceable edge rings can be found in U.S. patent application Ser. No. 14/705,430, filed on May 6, 2015, the entire contents of which is incorporated herein by reference. Example configurations for substrate supports including moveable edge rings can be found in Patent Cooperation Treaty Application No. US2017/043527, filed on Jul. 24, 2017 and Patent Cooperation Treaty Application No. US2017/062769, filed on Nov. 21, 2017, the entire contents of which are incorporated herein by reference.

In some configurations and process conditions, a position (e.g., height) of a moveable edge ring may affect process characteristics related to etch rate uniformity, including, but not limited to, characteristics of a plasma sheath such as a thickness of the plasma sheath, conformality of the plasma sheath around edge ring features, a voltage coupled to the edge ring, etc. For example, the position of the edge ring may affect ion trajectories near an edge of the substrate. Changes to the process characteristics caused by the position of the edge ring may also be affected (e.g., increased or decreased) by a distance between the edge ring and the edge of the substrate. Accordingly, edge ring configuration (e.g., shape, geometry, etc.) and position may impose constraints on plasma sheath tunability. Process characteristics and tunability are further affected by erosion of the edge ring, and edge ring configuration may determine how often the edge ring is replaced due to erosion.

A material of the edge ring may impose further constraints on plasma sheath tunability. For example, plasma sheath tunability may be limited when the edge ring is fully dielectric (e.g., comprised of quartz, ceramic, etc.) and a low radio frequency (RF) bias frequency is used (e.g., 1 MHz or less). In some examples, air and vacuum gaps between the edge ring and other components of the substrate support for different positions of the edge ring may impose constraints on impedance tunability. In other examples, a lift pin provided to raise and lower the edge ring may increase the likelihood of plasma arcing and dropouts when the edge ring is in a raised position.

Edge rings according to the principles of the present disclosure include various moveable edge ring configurations, including configurations having moveable inner and outer edge rings. For example, various configurations of multiple moveable edge rings and fixed (i.e., non-moveable) edge rings may be used to improve control of ion flux and tilt behaviors to control the etch rate over a greater radial range of the substrate.

In one example, an edge ring includes a fixed inner edge ring, a moveable inner edge ring, and a moveable outer edge ring. The edge rings may have an interlocking configuration. Dimensions (e.g., a distance, or width, between an inner and outer diameter) and materials of the edge rings are selected to optimize the response to adjustments of the respective heights of the moveable edge rings, which may be referred to herein as a “substrate response.” In other words, the rate, magnitude, and radial distance (relative to the edge of the substrate) of adjustments to process characteristics in response to movement of the edge rings can be determined in accordance with the dimensions of the edge rings.

For example, movement of the moveable outer edge ring may determine a control or inflection point, relative to a radius of the substrate, of a tunable characteristic (e.g., a plasma sheath, etch rate, etc.) while movement of the moveable inner edge ring adjusts the tunable characteristic between the inflection point and an edge of the substrate. In one example, the position of the moveable inner edge ring may control the substrate response at the outer edge (e.g., the outermost 0-5 mm) of the substrate while the position of the moveable outer edge ring may control the substrate response radially inward of the outer edge (e.g., in regions greater than 5 mm from the edge of the substrate).

Materials of the edge rings may be selected to further control tunability. For example, unwanted capacitance can be minimized or eliminated by using conductive or partially conductive moveable edge rings. For example, the fixed and moveable edge rings may comprise a combination of adjacent dielectric and conductive rings that provide RF coupling.

In another example, the moveable outer edge ring is supported on a moveable bottom ring that is located radially outside of the substrate support. Accordingly, the bottom ring is raised and lowered, using a lift pin, to correspondingly raise and lower the moveable outer edge ring. Since the outer edge ring and the bottom ring remain in contact with one another (i.e., in a “stack”), an impedance of the stack when raised is increased. The lift pin is also located outside of the substrate support. In other words, the lift pin does not pass through a baseplate or inner rings of the substrate support. Further, a gap (e.g., an air or vacuum gap) is not formed between the outer edge ring and the bottom ring when the outer edge ring is raised. Rather, a gap is formed below the bottom ring. In this example, the inner edge ring and the moveable outer edge ring may not have an interlocking configuration.

In another example, the substrate support includes a fixed inner ring and a moveable outer edge ring. The moveable outer edge ring has an interlocking configuration with a middle ring and is further supported on a bottom ring. The lift pin is located outside of the substrate support and passes through the bottom ring to raise and lower the moveable outer edge ring. In some examples of this configuration, the moveable outer edge ring may be powered via a conductive lift pin. For example, the lift pin may be actively or passively (e.g., capacitively) conductively coupled to RF power through the substrate support. The moveable outer edge ring may include an embedded metal mesh in conductive contact with the lift pin.

In another example, one or both inner and outer edge rings (either moveable or not moveable) may have a chamfered upper surface. For example, respective upper surfaces of one or more of the edge rings may slope upward as a distance from the substrate increases.

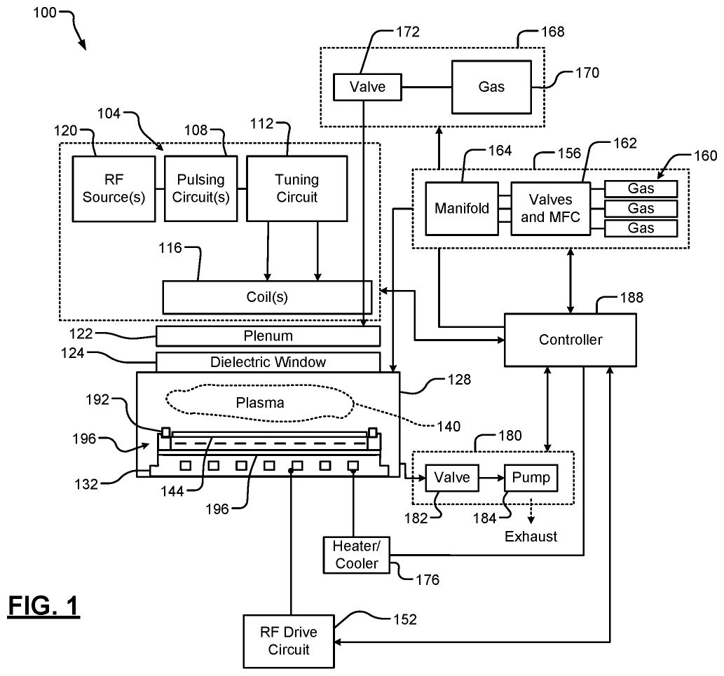

Referring now to FIG. 1, an example of a substrate processing system 100 according to the present disclosure is shown. While a specific substrate processing system 100 is shown as an example, the principles of the present disclosure may be applied to other types of substrate processing systems and chambers, such as a substrate processing system that generates plasma in-situ, that implements remote plasma generation and delivery (e.g., using a plasma tube, a microwave tube), etc.

The substrate processing system 100 includes a coil driving circuit 104. A pulsing circuit 108 may be used to pulse the RF power on and off or vary an amplitude or level of the RF power. A tuning circuit 112 may be directly connected to one or more inductive coils 116. The tuning circuit 112 tunes an output of an RF source 120 to a desired frequency and/or a desired phase, matches an impedance of the coils 116 and splits power between the coils 116. In some examples, the coil driving circuit 104 may be replaced by a drive circuit as described further below in conjunction with controlling the RF bias.

In some examples, a plenum 122 may be arranged between the coils 116 and a dielectric window 124 to control the temperature of the dielectric window 124 with hot and/or cold air flow. The dielectric window 124 is arranged along one side of a processing chamber 128. The processing chamber 128 further comprises a substrate support (or pedestal) 132. The substrate support 132 may include an electrostatic chuck (ESC), or a mechanical chuck or other type of chuck. Process gas is supplied to the processing chamber 128 and plasma 140 is generated inside of the processing chamber 128. The plasma 140 etches an exposed surface of a substrate 144. A drive circuit 152 (such as one of those described below) may be used to provide an RF bias to an electrode in the substrate support 132 during operation.

A gas delivery system 156 may be used to supply a process gas mixture to the processing chamber 128. The gas delivery system 156 may include process and inert gas sources 160, a gas metering system 162 such as valves and mass flow controllers, and a manifold 164. A gas delivery system 168 may be used to deliver gas 170 via a valve 172 to the plenum 122. The gas may include cooling gas (air) that is used to cool the coils 116 and the dielectric window 124. A heater/cooler 176 may be used to heat/cool the substrate support 132 to a predetermined temperature. An exhaust system 180 includes a valve 182 and pump 184 to remove reactants from the processing chamber 128 by purging or evacuation.

A controller 188 may be used to control the etching process. The controller 188 monitors system parameters and controls delivery of the gas mixture, striking, maintaining and extinguishing the plasma, removal of reactants, supply of cooling gas, and so on. Additionally, as described below in detail, the controller 188 may control various aspects of the coil driving circuit 104 and the drive circuit 152. An edge ring 192 may be located radially outside of the substrate 134 during plasma processing. A height adjustment system 196 may be used to adjust a height of the edge ring 192 (i.e., the edge ring 192 may be tunable) relative to the substrate 134 based on one or more parameters as described below in more detail. The controller 188 may be used to control the height adjustment system 196.

The edge ring 192 may correspond to a top edge ring, which may be supported by a bottom ring or a middle ring (not shown in FIG. 1). In some examples, the edge ring 192 may be further supported by a stepped portion of a ceramic layer 198 as described below in more detail. In some examples, the edge ring 192 may be removable (e.g., using a robot, via an airlock, while the processing chamber 128 is under vacuum). In still other examples, the edge ring 192 may be both tunable and removable.

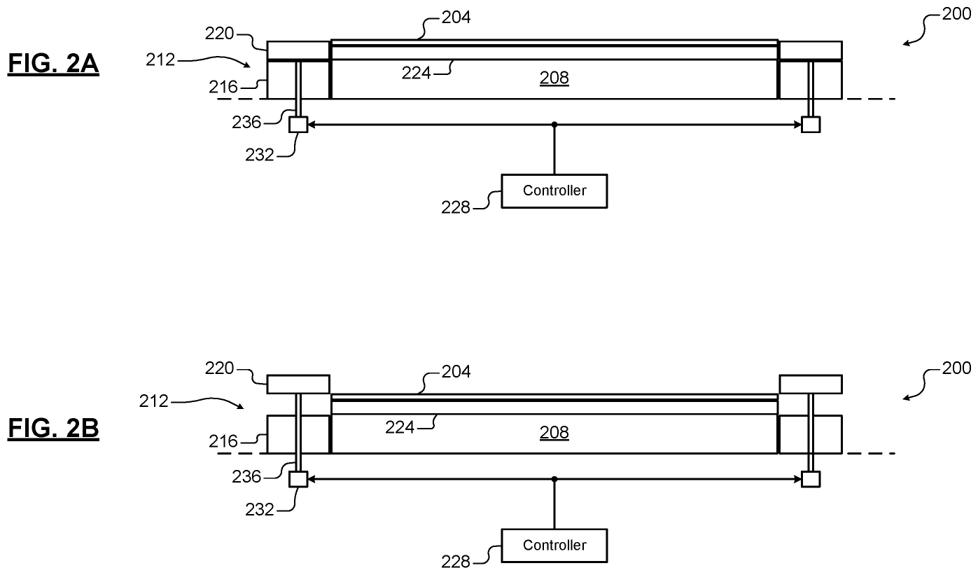

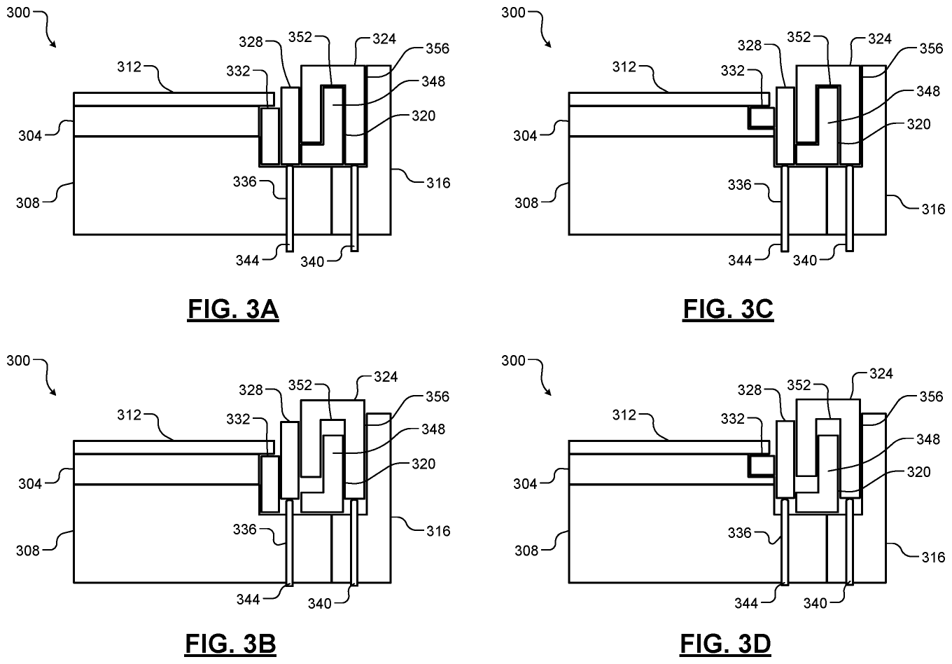

Referring now to FIGS. 2A and 2B, an example substrate support 200 having a substrate 204 arranged thereon is shown. The substrate support 200 may include a base or pedestal having an inner portion (e.g., corresponding to an ESC, a conductive baseplate, etc.) 208 and an outer portion 212. In examples, the outer portion 212 may be independent from, and moveable in relation to, the inner portion 208. For example, the outer portion 212 may include a bottom ring 216 and a top edge ring 220. The substrate 204 is arranged on the inner portion 208 (e.g., on a ceramic layer 224) for processing. A controller 228 communicates with one or more actuators 232 to selectively raise and lower the edge ring 220. For example, the edge ring 220 may be raised and/or lowered to adjust a pocket depth of the substrate support 200 during processing. In another example, the edge ring 220 may be raised to facilitate removal and replacement of the edge ring 220.

For example only, the edge ring 220 is shown in a fully lowered position in FIG. 2A and in a fully raised position in FIG. 2B. As shown, the actuators 232 correspond to pin actuators configured to selectively extend and retract pins 236 in a vertical direction. Other suitable types of actuators may be used in other examples. For example only, the edge ring 220 corresponds to a ceramic or quartz edge ring, although other suitable materials may be used (e.g., silicon carbide, yttria, etc.). In some examples, the edge ring 220 may be conductive. In FIG. 2A, the controller 228 communicates with the actuators 232 to directly raise and lower the edge ring 220 via the pins 236. In some examples, the inner portion 208 is moveable relative to the outer portion 212.

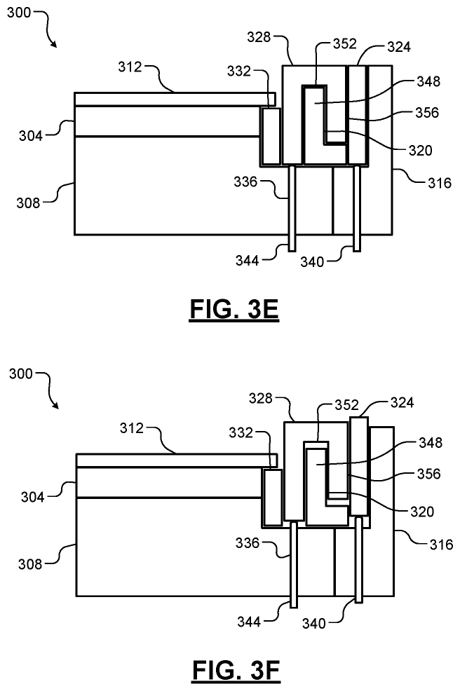

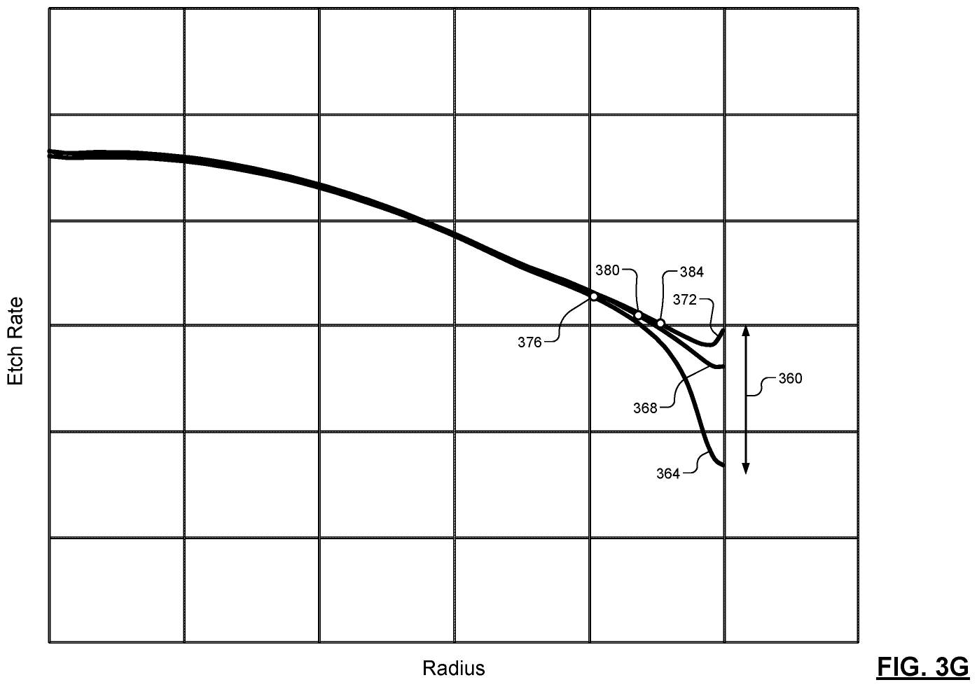

Edge ring configurations of an example substrate support 300 according to the present disclosure are shown in more detail in FIGS. 3A, 3B, 3C, 3D, 3E, and 3F. The substrate support 300 includes a ceramic layer 304 arranged on a baseplate (e.g., of an ESC) 304. The ceramic layer 304 is configured to support a substrate 312 arranged thereon for processing. In FIGS. 3A and 3B, the ceramic layer 304 has a non-stepped configuration. In FIGS. 3C and 3D, the ceramic layer 304 has a stepped configuration. The substrate support 300 includes a side or bottom ring 316 and a middle ring 320 that support a moveable outer edge ring 324. The substrate support 300 further includes a moveable inner edge ring 328 and a fixed inner ring 332. The outer edge ring 324 and the inner edge ring 328 may together be referred to as an edge ring. In some examples, the rings 324, 328, and 332 may be referred to as top or upper rings. In FIGS. 3A and 3C, the outer edge ring 324 and the inner edge ring 328 are shown in a lowered position. Conversely, in FIGS. 3B and 3D, the outer edge ring 324 and the inner edge ring 328 are shown in a raised position. In one example, the inner edge ring 328 and the fixed inner ring 332 are conductive and the outer edge ring 324 is dielectric. In another example, the inner edge ring 328 and the fixed inner ring 332 are dielectric and the outer edge ring 324 is conductive.

One or more vias or guide channels 336 may be formed through the baseplate 308 and/or the side ring 316 to accommodate lift pins 340 and 344 arranged to selectively raise and lower respective ones of the outer edge ring 324 and the inner edge ring 328. For example, the guide channels 336 function as pin alignment holes for respective ones of the lift pins 340 and 344. The lift pins 340 and 344 may comprise an erosion-resistant material (e.g., sapphire). An outer surface of the lift pins 340 and 344 may be polished smooth to reduce friction between the lift pins 340 and 344 and structural features of the baseplate 308 and the side ring 316 to facilitate movement. Upper ends of the lift pins 340 and 344 may be rounded to minimize a contact area between pins 340 and 344 and respective ones of the edge rings 324 and 328.

The middle ring 320 may include a guide feature 348. For example, the guide feature 348 corresponds to a raised annular rim that extends upward from the middle ring 320. The outer edge ring 324 includes an annular bottom groove 352 arranged to receive the guide feature 348. For example, a profile (i.e., cross-section) shape of the outer edge ring 324 may generally correspond to a “U” shape configured to receive the guide feature 348, although other suitable shapes may be used.” A profile shape of the middle ring 320 may generally correspond to an “L” shape including the guide feature 348. Accordingly, a bottom surface of the outer edge ring 324 is configured to be complementary to (i.e., interlocking with) an upper surface of the middle ring 320, and respective vertical portions of the outer edge ring 324 are supported on stepped portions of the middle ring 320 and the side ring 316. The inner edge ring 328 may have a generally columnar profile shape and is located radially inward of and adjacent to both the outer edge ring 324 and the stepped portion of the middle ring 320.

Further, an interface 356 between the outer edge ring 324, the inner edge ring 328, the middle ring 320, and the side ring 316 is labyrinthine. In other words, the lower surface of the outer edge ring 324 and, correspondingly, the interface 356, includes multiple changes of direction (e.g., 90 degree changes of direction, upward and downward steps, alternating horizontal and vertical orthogonal paths, etc.) rather than providing a direct (e.g., line of sight) path between the outer edge ring 324 and the inner edge ring 328, the middle ring 320, and the side ring 316 to interior structures of the substrate support 300. Typically, a likelihood of plasma and process material leakage may be increased in substrate supports including multiple interfacing rings. This likelihood may be further increased when the moveable outer edge ring 324 and/or inner edge ring 328 are raised during processing. Accordingly, the interface 356 (and, in particular, the profile of the outer edge ring 324) is configured to prevent process materials, plasma, etc. from reaching interior structures of the substrate support 300.

The outer edge ring 324 and the inner edge ring 328 may be raised and lowered independently of one another and to different heights relative to the substrate support 300. For example, movement of the outer edge ring 324 may determine a inflection point, relative to a radius of the substrate 312, of changes to a plasma sheath (and, correspondingly, changes to an etch rate) that are achievable in response to movement of the inner edge ring 328. Conversely, movement of the inner edge ring 328 adjusts the plasma sheath between the inflection point and an edge of the substrate 312. According, a controller (e.g., the controller 228) is configured to selectively adjust respective positions of the outer edge ring 324 and the inner edge ring 328 to adjust the inflection point and the etch rate in a region defined by the inflection point as described below in more detail.

The substrate support 300 is shown in another non-stepped configuration in FIGS. 3E and 3F. In this example, the inner edge ring 328 is “U”-shaped and includes the annular bottom groove 352 arranged to receive the guide feature 348 of the middle ring 320. In other words, the inner edge ring 328 of FIGS. 3E and 3F has a configuration similar to the outer edge ring 324 of FIGS. 3A-3D. The “L”-shaped profile of the middle ring 320 may be reversed (i.e., reversed in a horizontal direction) relative to the middle ring 320 as shown in FIGS. 3A-D. Conversely, the outer edge ring 324 may have a generally columnar profile shape and is located radially outward of and adjacent to both the inner edge ring 328 and the stepped portion of the middle ring 320 and radially inward of the side ring 316. In other words, the outer edge ring 324 of FIGS. 3E and 3F has a configuration similar to the inner edge ring 328 of FIGS. 3A-3D.

Although each of the example substrate supports 300 shown in FIGS. 3A-3F includes two moveable rings 324 and 328 (and respective lifter pins 340 and 348), in other examples the substrate supports 300 may only include one moveable ring. For example, one of the outer edge ring 324 and the inner edge ring 328 may be fixed.

Referring now to FIG. 3G and with continued reference to FIGS. 3A, 3B, 3C, 3D, 3E, and 3F, an adjustability (or, tunability) of an etch rate relative to a radius of the substrate 312 is shown. Although tunability of the etch rate is described, the tunability relative to adjustments of the outer edge ring 324 and the inner edge ring 328 may also correspond to other process characteristics related to the etch rate including, but not limited to, the plasma sheath, ion flux, and ion incident angle, etc.

The etch rate may generally decrease as the radius increases. In other words, the etch rate may decrease near an outer edge of the substrate 312. Accordingly, the outer and inner edge rings 324 and 328 may be raised or lowered to adjust (e.g., decrease or increase) the etch rate at the outer edge of the substrate 312 within a tunable range as shown at 360. As described herein, the tunable range 360 may correspond to a tunable range of the magnitude of the etch rate within a given radial region at the outer edge of the substrate 312.

Etch rate curves 364, 368, and 372 are shown for respective first, second, and third positions of the outer edge ring 324. For example, the etch rate curves 364 and 368 may correspond to different raised positions while the etch rate curve 372 corresponds to a lowered (e.g., a fully lowered) position. Respective inflection points 376, 380, and 384 of the etch rate curves 364, 368, and 372 indicate a tunable radial range of the etch rate at each position of the outer edge ring. The tunable radial range corresponds to a width of a radial region that is tunable in accordance with the position of the outer edge ring 324. Accordingly, the etch rate in a region of the substrate 312 outside of (i.e., greater than) the radius indicated by the inflection point may be adjustable by moving the inner edge ring 328. Conversely, the etch rate in a region inside of (i.e., less than) the radius indicated by the inflection point may not be adjustable by moving the inner edge ring 328. In this manner, the tunable radial range can be adjusted by adjusting the position of the outer edge ring 324.

At each position of the outer edge ring 324, the etch rate within the respective tunable radial range is adjustable in accordance with the position of the inner edge ring 328. In other words, while adjusting the position of the outer edge ring 324 adjusts the width of the tunable radial range (i.e., adjusts a distance from the outer edge at which the etch rate is adjustable), adjusting the position of the inner edge ring 328 adjusts the etch rate (i.e., the magnitude of the etch rate) within the tunable radial range.

Dimensions (e.g., a distance, or width, between an inner and outer diameter) and materials of the outer and inner edge rings 324 and 328 and the fixed inner ring 332 may be selected to further optimize the response of the etch rate to adjustments of the respective heights of the moveable outer and inner edge rings 324 and 328. In other words, etch rate behavior in response to positions of the outer and inner edge rings 324 and 328 (e.g., a rate of change in the etch rate, the tunable range 360, the tunable radial range, etc.) can be further determined by dimensions of the outer and inner edge rings 324 and 328 and the fixed inner ring 332. Similarly, respective materials of the outer and inner edge rings 324 and 328 and the fixed inner ring 332 may be selected to further control etch rate response. Materials include, but are not limited to, quartz, ceramic, silicon carbide (SiC), and aluminum nitride (AlN).

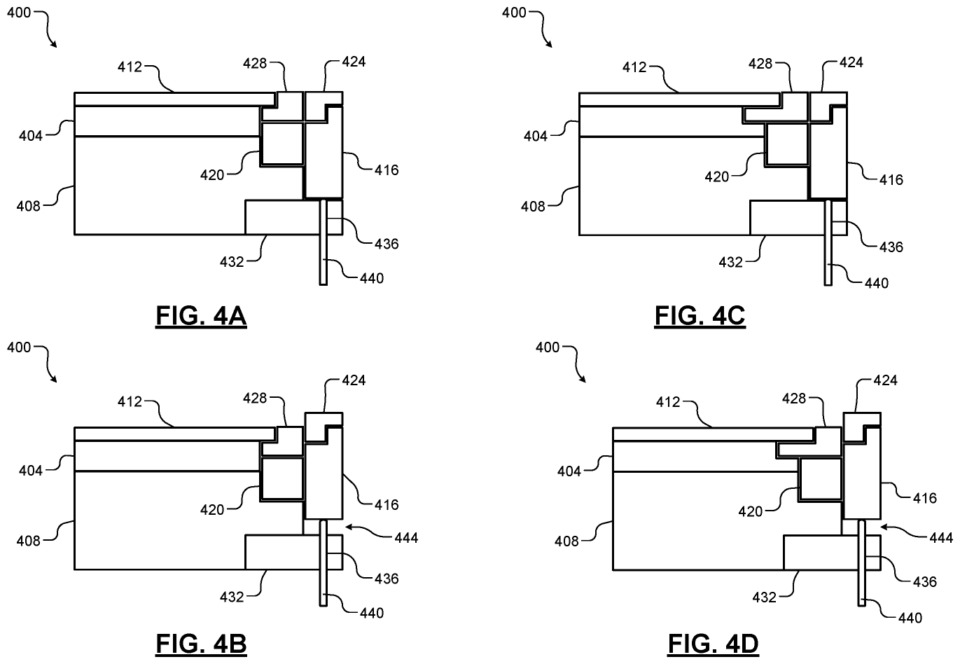

Edge ring configurations of another example substrate support 400 according to the present disclosure are shown in more detail in FIGS. 4A, 4B, 4C, and 4D. The substrate support 400 includes a ceramic layer 404 arranged on a baseplate (e.g., of an ESC) 404. The ceramic layer 404 is configured to support a substrate 412 arranged thereon for processing. In FIGS. 4A and 4B, the ceramic layer 304 has a non-stepped configuration. In FIGS. 4C and 4D, the ceramic layer 404 has a stepped configuration.

The substrate support 400 includes a bottom ring 416 and a middle ring 420. The bottom ring 416 supports a moveable outer edge ring 424. The substrate support 400 further includes an inner edge ring 428. The outer edge ring 424 and the inner edge ring 428 may together be referred to as an edge ring. In this example, the inner edge ring 428 is fixed (i.e., not moveable), but in other examples the inner edge ring 428 may be moveable. In some examples, the edge rings 424 and 428 may be referred to as top or upper rings. In FIGS. 4A and 4C, the outer edge ring 424 is shown in a lowered position. Conversely, in FIGS. 4B and 4D, the outer edge ring 424 is shown in a raised position. The substrate support may include an isolation plate or ring 432 arranged to support the bottom ring 416. As shown, the outer edge ring 424 has an inverted “L” profile shape. For example, the outer edge ring 424 has an inner vertical portion supported on a stepped inner portion of the bottom ring 416.

A via or guide channel 436 may be formed through the isolation ring 432 to accommodate a lift pin 440 arranged to selectively raise and lower a stack including the bottom ring 416 and the outer edge ring 424. In other words, since the outer edge ring 424 is arranged on the bottom ring 416, raising and lowering the bottom ring 416 correspondingly raises and lowers the outer edge ring 424. Accordingly, the outer edge ring 424 and the bottom ring 416 remain in contact with one another when raised and an impedance of the outer edge ring 424 and the bottom ring 416 is greater than an impedance of the outer edge ring 424 alone. In other words, in this example, the raised outer edge ring 424 and bottom ring 416 together have a greater impedance than examples where only the outer edge ring 424 is raised. Further, since the bottom ring 416 and the lift pin 440 are located radially outside of the baseplate 408, the lift pin 440 does not pass through the baseplate 408 or other inner rings of the substrate support 400. Accordingly, plasma lightup and plasma and process material leakage into internal gaps within the substrate support 400 are minimized.

In examples where the outer edge ring 424 is raised separately from the bottom ring 416, a gap (e.g., an air or vacuum gap) is formed between the outer edge ring 424 and the bottom ring 416 when the outer edge ring 424 is raised. Conversely, in the present example, a gap 444 is formed below the bottom ring 416. In other words, the gap 444 is lowered relative to the upper surface of the substrate support 400 and the substrate 412. Accordingly, plasma lightup and plasma and process material leakage in a region near the substrate support 400 and the outer and inner edge rings 424 and 428 can be minimized.

Similar to the examples described above, dimensions and materials of the outer and inner edge rings 424 and 428 may be selected to further optimize the response of the etch rate to adjustments of the height of the moveable outer edge ring 424. For example, a thickness (i.e., height) of the inner edge ring 428 may be adjusted to change a tunable range or radial range of the response. In one example, the outer edge ring 424 comprises SiC, quartz, or ceramic, the inner edge ring 428 comprises SiC, quartz, or ceramic, the middle ring 420 comprises SiC, quartz, or ceramic, and the bottom ring 416 comprises ceramic or quartz.

Although the example substrate supports 400 shown in FIGS. 4A-4D include only one lift pin 440 and the stack including the bottom ring 416 and the outer edge ring 424, in other examples the substrate supports 400 may include multiple moveable rings/and/or stacks and corresponding lift pins. For example, each of the bottom ring 416 and the outer edge ring 424 may be split into two separate rings (e.g., concentric inner and outer ring portions) that can be independently raised with a corresponding lift pin.

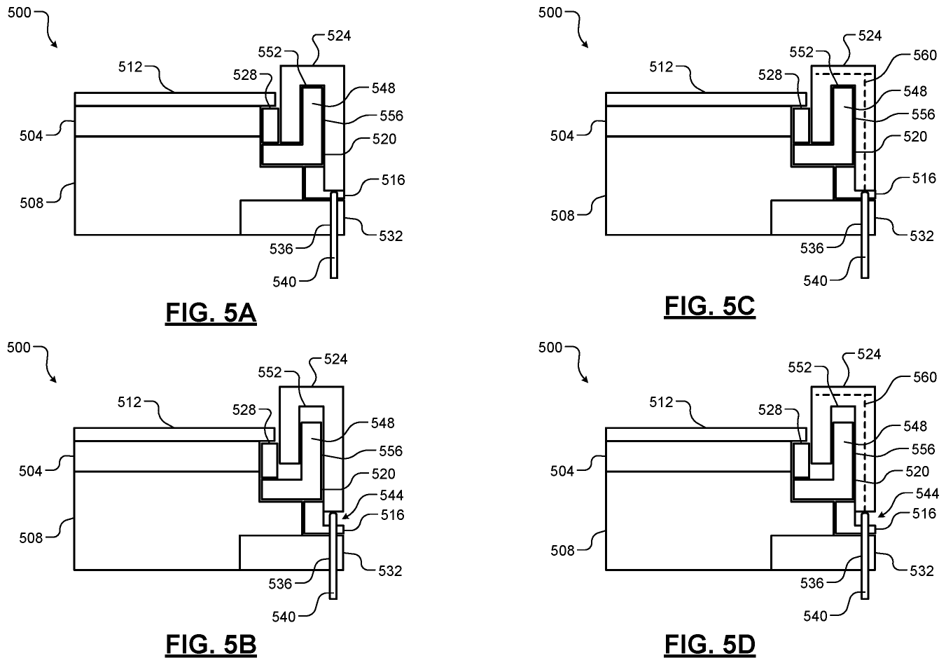

Edge ring configurations of another example substrate support 500 according to the present disclosure are shown in more detail in FIGS. 5A, 5B, 5C, and 5D. The substrate support 500 includes a ceramic layer 504 arranged on a baseplate (e.g., of an ESC) 508. The ceramic layer 504 is configured to support a substrate 512 arranged thereon for processing. As shown, the ceramic layer 504 has a non-stepped configuration. In other examples, the ceramic layer 504 may have a stepped configuration.

The substrate support 500 includes a bottom ring 516 and a middle ring 520. The bottom ring 516 supports a moveable outer edge ring 524. The substrate support 500 further includes an inner edge ring 528. The outer edge ring 524 and the inner edge ring 528 may together be referred to as an edge ring. In this example, the inner edge ring 528 is fixed (i.e., not moveable), but in other examples the inner edge ring 528 may be moveable. In some examples, the edge rings 524 and 528 may be referred to as top or upper rings. In FIGS. 5A and 5C, the outer edge ring 524 is shown in a lowered position. Conversely, in FIGS. 5B and 5D, the outer edge ring 524 is shown in a raised position. The substrate support may include an isolation plate or ring 532 arranged to support the bottom ring 516.

A via or guide channel 536 may be formed through the isolation ring 532 and the bottom ring 516 to accommodate a lift pin 540 arranged to selectively raise and lower the outer edge ring 524. The bottom ring 516 and the lift pin 540 are located radially outside of the baseplate 508. Accordingly, the lift pin 540 does not pass through the baseplate 508 or other inner rings of the substrate support 500 and plasma lightup and plasma and process material leakage into internal gaps within the substrate support 500 are minimized. Further, an outer portion of the bottom ring 516 is stepped and a portion of the outer edge ring 524 arranged to interface with the lift pin 540 extends below an upper surface of the bottom ring 516. In other words, the outer edge ring 524 is supported on the stepped portion of the bottom ring 516. Accordingly, a gap (e.g., an air or vacuum gap) 544 between the outer edge ring 524 and the bottom ring 516 when the outer edge ring 524 is raised is formed below the upper surface of the bottom ring 516. In other words, the gap 544 is lowered relative to the upper surface of the substrate support 500 and the substrate 512. Accordingly, plasma lightup and plasma and process material leakage in a region near the substrate support 500 and the outer and inner edge rings 524 and 528 can be minimized.

The middle ring 520 may include a guide feature 548 similar to the guide feature 348 described above. For example, the guide feature 548 corresponds to a raised annular rim that extends upward from the middle ring 520. The outer edge ring 524 includes an annular bottom groove 552 arranged to receive the guide feature 548. For example, a profile (i.e., cross-section) shape of the outer edge ring 524 may generally correspond to a “U” shape configured to receive the guide feature 548, although other suitable shapes may be used. A profile shape of the middle ring 520 may generally correspond to an “L” shape including the guide feature 548. Accordingly, a bottom surface of the outer edge ring 524 is configured to be complementary to (i.e., interlocking with) an upper surface of the middle ring 520 and an interface 556 between the outer edge ring 524, the inner edge ring 528, and the middle ring 520 is labyrinthine. Respective vertical portions of the outer edge ring 524 are supported on stepped portions of the middle ring 520 and the bottom ring 516. The inner edge ring 528 may have a generally columnar profile shape and is located radially inward of and adjacent to the outer edge ring 524. The inner edge ring 528 may be supported on the stepped portion of the middle ring 520.

Similar to the examples described above, dimensions and materials of the outer and inner edge rings 524 and 528 may be selected to further optimize the response of the etch rate to adjustments of the height of the moveable outer edge ring 524. For example, relative widths of the outer edge ring 424 and the inner edge ring 528 may be adjusted to change a tunable range or radial range of the response. In one example, the outer edge ring 524 comprises SiC, quartz, or ceramic, the inner edge ring 528 comprises SiC, quartz, or ceramic, the middle ring 520 comprises SiC, quartz, or ceramic, and the bottom ring 516 comprises ceramic or quartz.

As shown in FIGS. 5C and 5D, the lift pin 540 is conductive and provides power to the outer edge ring 524. For example, the lift pin 540 may be actively or passively (e.g., capacitively) conductively coupled to RF power through the substrate support 500 (e.g., via the bottom ring 516. The outer edge ring 524 may include an embedded metal mesh 560 in conductive contact with the lift pin 540. Accordingly, when RF power (e.g., an RF voltage) is provided to the substrate support 500, the RF voltage may also be provided to the outer edge ring 524 via the lift pin 540 and the metal mesh 560. Examples configurations of edge rings including an embedded metal mesh can be found in U.S. Patent Application No. 62/882,890, filed on Aug. 5, 2019, the entire contents of which is incorporated herein by reference.

The outer edge ring 524 including the embedded metal mesh 560 may be formed used various methods. In one example, a mixture of ceramic powder, binder and liquid may be pressed into ceramic layer sheets (which may be referred to as “green sheets”). The green sheets are dried and holes are punched in the green sheets to form vias. The vias are filled with conductive material (e.g., a slurry of conducting powder). Layers of the metal mesh 560 are formed on respective ones of the green sheets. For example only, layers of the metal mesh 560 are formed on the ceramic green sheets by screen printing a slurry of conducting powder (e.g. W, WC, doped SiC, MoSi₂, etc.), pressing a precut metal foil, spraying a slurry of conducting powder, and/or other suitable techniques. The ceramic green sheets are then aligned and bonded together by sintering to form a contiguous structure corresponding to the outer edge ring 524.

Although the example substrate supports 500 shown in FIGS. 5A-5D include only one lift pin 540 and moveable ring (i.e., the outer edge ring 524), in other examples the substrate supports 500 may include multiple moveable rings and corresponding lift pins. For example, the outer edge ring 524 may be split into two separate rings (e.g., concentric inner and outer ring portions) that can be independently raised with a corresponding lift pin.

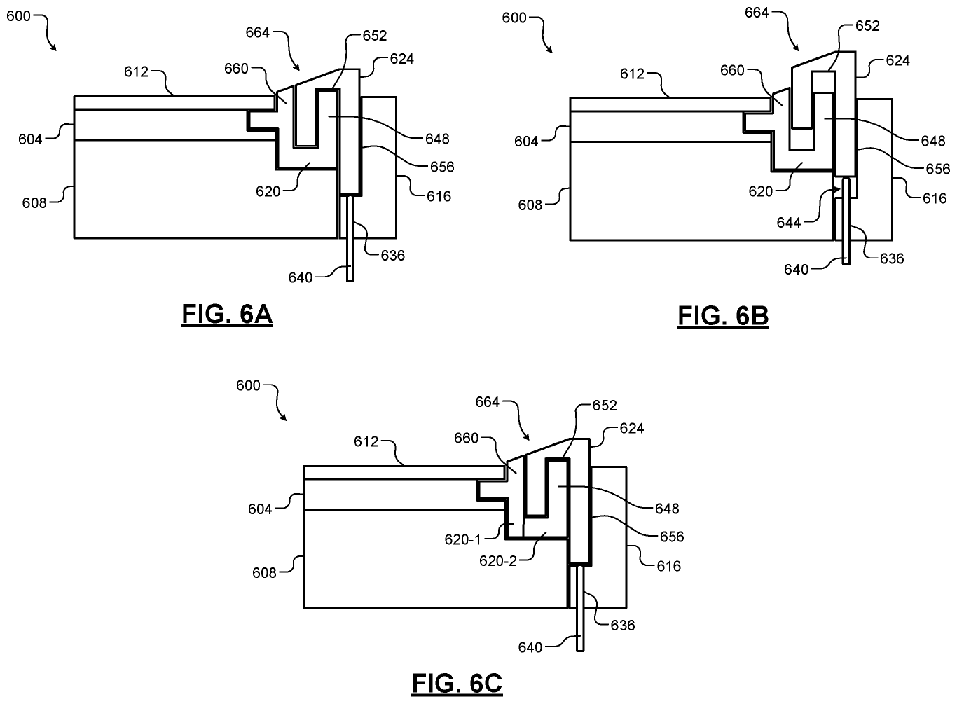

An edge ring configuration of another example substrate support 600 according to the present disclosure is shown in more detail in FIGS. 6A, 6B, and 6C. The substrate support 600 includes a ceramic layer 604 arranged on a baseplate (e.g., of an ESC) 608. The ceramic layer 604 is configured to support a substrate 612 arranged thereon for processing. As shown, the ceramic layer 604 has a stepped configuration. In other examples, the ceramic layer 604 may have a non-stepped configuration.

The substrate support 600 includes a side or bottom ring 616 and an inner or middle ring 620. The side ring 616 and the middle ring 620 support a moveable outer edge ring 624. In some examples, the outer edge ring 624 may be referred to as a top or upper ring. In FIG. 6A, the outer edge ring 624 is shown in a lowered position. Conversely, in FIG. 6B, the outer edge ring 624 is shown in a raised position. In FIG. 6C, the middle ring 620 may comprise two separate rings 620-1 and 620-2. In some examples, each of the middle ring 620 and the outer edge ring 624 are conductive. In other examples, each of the middle ring 620 and the outer edge ring 624 are dielectric.

A via or guide channel 636 may be formed through the side ring 616 to accommodate a lift pin 640 arranged to selectively raise and lower the outer edge ring 624. The side ring 616 and the lift pin 640 are located radially outside of the baseplate 608. Accordingly, the lift pin 640 does not pass through the baseplate 608 or other inner rings of the substrate support 600 and plasma lightup and plasma and process material leakage into internal gaps within the substrate support 600 are minimized. Further, an inner portion of the side ring 616 is stepped and a portion of the outer edge ring 624 arranged to interface with the lift pin 640 is supported on the stepped portion of the side ring 616. Accordingly, a gap (e.g., an air or vacuum gap) 644 between the outer edge ring 624 and the side ring 616 when the outer edge ring 624 is raised is enclosed by the side ring 616 to minimize plasma lightup and plasma and process material leakage.

The middle ring 620 may include a guide feature 648 similar to the guide features 348 and 548 described above. For example, the guide feature 648 corresponds to a raised annular rim that extends upward from the middle ring 620. The outer edge ring 624 includes an annular bottom groove 652 arranged to receive the guide feature 648. For example, a profile (i.e., cross-section) shape of the outer edge ring 624 may generally correspond to a “U” shape configured to receive the guide feature 648, although other suitable shapes may be used. Accordingly, a bottom surface of the outer edge ring 624 is configured to be complementary to (i.e., interlocking with) an upper surface of the middle ring 620 and an interface 656 between the outer edge ring 624 and the middle ring 620 is labyrinthine.

A profile shape of the middle ring 620 may generally correspond to a “U” shape. An inner portion 660 and the guide feature 648 of the middle ring 620 correspond to vertical portions of the “U” shape. Respective vertical portions of the outer edge ring 624 are supported on a stepped portion the side ring 616 and a horizontal portion of the middle ring 620 between the inner portion 660 and the guide feature 648.

Similar to the examples described above, dimensions and materials of the outer edge ring 624 and the middle ring 620 may be selected to further optimize the response of the etch rate to adjustments of the height of the moveable outer edge ring 624. For example, relative heights and widths of the outer edge ring 624 and an inner portion 660 of the middle ring 620 may be adjusted to change a tunable range or radial range of the response. In one example, the outer edge ring 624 comprises SiC, quartz, or ceramic, the middle ring 620 comprises SiC, quartz, or ceramic, and the side ring 616 comprises ceramic or quartz.

In this example, one or both of the inner portion 660 of the middle ring 620 and the outer edge ring 624 may have a chamfered upper surface 664. For example, respective upper surfaces of the inner portion 660 of the middle ring 620 and the outer edge ring 624 slope upward as a distance (i.e., a radial distance) from the substrate 612 increases. Although as shown the inner portion 660 of the middle ring 620 and the outer edge ring 624 have a same slope (i.e., a same chamfer angle), in other examples the slopes may be different. The slope may be selected to further adjust the tunable range and tunable radial range of the etch rate.

Although the example substrate supports 600 shown in FIGS. 6A-6C include only one lift pin 640 and moveable ring (i.e., the outer edge ring 624), in other examples the substrate supports 600 may include multiple moveable rings and corresponding lift pins. For example, the outer edge ring 624 may be split into two separate rings (e.g., concentric inner and outer ring portions) that can be independently raised with a corresponding lift pin.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate support, comprising:
an outer edge ring configured to be raised and lowered relative to the substrate support via one or more lift pins, wherein the outer edge ring is further configured to interface with a guide feature extending upward from a middle ring of the substrate support; and
an inner edge ring located radially inward of the outer edge ring, wherein the inner edge ring is configured to be raised and lowered, independently of the outer edge ring, relative to the substrate support via one or more lift pins.

2. The substrate support of claim 1, further comprising a fixed inner ring located radially inward of the inner edge ring.

3. The substrate support of claim 1, further comprising the middle ring including the guide feature.

4. The substrate support of claim 3, wherein the guide feature corresponds to a raised annular rim.

5. The substrate support of claim 4, wherein the outer edge ring includes an annular groove arranged to receive the raised annular rim.

6. A system comprising the substrate support of claim 1 and further comprising a controller configured to (i) adjust a position of the outer edge ring to adjust an inflection point of a plasma sheath, wherein the inflection point determines a tunable radial range of the plasma sheath and (ii) adjust a position of the inner edge ring to adjust the plasma sheath within the tunable radial range.

7. A substrate support, comprising:
an inner edge ring;
an outer edge ring located radially outward of the inner edge ring; and
a bottom ring, wherein the outer edge ring is arranged on the bottom ring, wherein the bottom ring is configured to be raised and lowered relative to the substrate support via one or more lift pins, and wherein raising and lowering the bottom ring correspondingly raised and lowers the outer edge ring relative to the substrate support.

8. The substrate support of claim 7, further comprising a fixed inner edge ring located radially inward of the outer edge ring.

9. The substrate support of claim 7, further comprising an isolation ring, wherein the bottom ring is arranged on the isolation ring, and wherein the isolation ring includes visa arranged to receive the one or more lift pins.

10. The substrate support of claim 9, wherein the one or more lift pins pass through the vias radially outward of a baseplate of the substrate support.

11. A system comprising the substrate support of claim 7 and further comprising a controller configured to adjust a position of the outer edge ring to adjust a plasma sheath.

12. A substrate support, comprising:
an outer edge ring configured to be raised and lowered relative to the substrate support via one or more lift pins, wherein the outer edge ring is further configured to interface with a guide feature extending upward from a middle ring of the substrate support the edge ring;
an inner edge ring located radially inward of the outer edge ring; and
a bottom ring including a stepped outer portion, wherein the outer edge ring is arranged on the stepped outer portion of the bottom ring, and wherein the stepped outer portion includes via arranged to receive the one or more lift pins.

13. The substrate support of claim 12, further comprising the middle ring including the guide feature.

14. The substrate support of claim 13, wherein the guide feature corresponds to a raised annular rim.

15. The substrate support of claim 14, wherein the outer edge ring includes an annular groove arranged to receive the raised annular rim.

16. A system comprising the substrate support of claim 15 and further comprising a controller configured to adjust a position of the outer edge ring to adjust a plasma sheath.

17. The substrate support of claim 12, wherein at least one lift pin of the one or more lift pins is conductive.

18. The substrate support of claim 17, wherein the at least one lift pin is configured to receive power provided to the substrate support.

19. The substrate support of claim 18, wherein the outer edge ring is configured to receive the power from the at least one lift pin.

20. The substrate support of claim 19, wherein the outer edge ring includes an embedded metal mesh arranged to contact the at least one lift pin.

21. A substrate support, comprising:
a middle ring including an inner portion and a guide feature extending upward from the middle ring; and
an outer edge ring located radially outward of the inner portion of the middle ring and configured to be raised and lowered relative to the substrate support via one or more lift pins, wherein the outer edge ring is further configured to interface with the guide feature,
wherein at least one of respective upper surfaces of the inner portion of the middle ring and the outer edge ring is chamfered.

22. The substrate support of claim 21, further comprising a side ring including a stepped inner portion, wherein the outer edge ring is arranged on the stepped inner portion of the side ring, and wherein the stepped inner portion includes via arranged to receive the one or more lift pins

23. The substrate support of claim 21, wherein the guide feature corresponds to a raised annular rim.

24. The substrate support of claim 23, wherein the outer edge ring includes an annular groove arranged to receive the raised annular rim.

25. A system comprising the substrate support of claim 21 and further comprising a controller configured to adjust a position of the outer edge ring to adjust a plasma sheath.

26. The substrate support of claim 21, wherein each of the respective upper surfaces of the inner portion of the middle ring and the outer edge ring is chamfered.

27. The substrate support of claim 21, wherein the at least of the respective upper surfaces of the inner portion of the middle ring and the outer edge ring slopes upward as a radial distance increases.
